(19) United States
(12) Patent Application Publication
(10) Pub. No.: US 2015/0035542 A1
(43) Pub. Date: Feb. 5, 2015

(54) METHOD OF DETECTING OSCILLATIONS USING COHERENCE

(71) Applicant: Ning Zhou, Richland, WA (US)

(72) Inventor: Ning Zhou, Richland, WA (US)

(73) Assignee: BATTELLE MEMORIAL INSTITUTE, Richland, WA (US)

(21) Appl. No.: 13/958,008

(22) Filed: Aug. 2, 2013

(51) Int. Cl. G01R 31/08

(52) U.S. Cl. CPC G01R 31/08
USPC 324/539

(57) ABSTRACT

A method of detecting oscillations is disclosed. An input signal is received. A time delay is added to the input signal. A coherence between the input signal and the time-delayed input signal is estimated. The coherence is greater than a predetermined threshold. The time delay may be greater than or equal to one sampling interval.

### STATEMENT REGARDING FEDERALLY SPONSORED RESEARCH OR DEVELOPMENT

The invention was made with Government support under Contract DE-ACO5-76RLO1830, awarded by the U.S. Department of Energy. The Government has certain rights in the invention.

### TECHNICAL FIELD

This invention relates to detection of oscillations. More specifically, this invention relates to detecting oscillations by estimating a coherence between a signal and its time-delayed signal.

### BACKGROUND OF THE INVENTION

Oscillations in most systems and networks, such as power transmission systems, can be grouped into two categories: 1) free oscillations and 2) forced oscillations. Free oscillations are caused by the natural interactions among different dynamic devices within a network.

Take power grid systems, for example. Even under no external periodic influences, a power grid still oscillates at its natural frequency under small disturbances. Often, when the grid is under equilibrium conditions and the major disturbance is from small amplitude load changes, the natural responses to the free oscillations are called “ambient” noise (J. W. Pierre, D. J. Trudnowski, and M. K. Donnelly, “Initial results in electromechanical mode identification from ambient data,”IEEE Trans. on Power Syst., vol. 12, no. 3, pp. 1245-1251, August 1997). In comparison, forced oscillations are system responses to an external periodic perturbation. They may be caused by a probing injection intentionally injected into the grid (N. Zhou, J. W. Pierre, and J. F. Hauer. “Initial results in power system identification from injected probing signals using a subspace method,” IEEE Transactions on Power Systems, vol. 21, no. 3, pp. 1296-1302, August 2006) or a mistuned controller. Forced oscillations around a natural oscillation mode can incur sustained oscillations that lower system performance and increase the wear and tear of instruments (M. A. Magdy and F. Coowar, “Frequency domain analysis of power system forced oscillations,” IEE Proceedings on Generation, Transmission and Distribution, vol. 137, no. 4, pp. 261-268, July 1990). Oscillations around 10 Hz may cause annoying flickering light to human eyes (C. D. Vournas, N. Krassas, and B. C. Papadias. “Analysis of forced oscillations in a multi-machine power system,” International Conference on Control '91, pp. 443-448. IET, 1991).

To operate a network or system reliably and efficiently, it is desirable to detect, analyze, and categorize oscillations timely and accurately so that cause-effect knowledge can be established to support operation decisions. Processing forced oscillations as “ambient responses” often results in a very low damping mode from a mode estimation algorithm (e.g., the Yule-Walker method) and may even lead to false alarms and mistaken reactions. To determine effective remedial reactions, oscillations must be detected and categorized accurately at their early stages.

### SUMMARY OF THE INVENTION

The present invention is directed to methods of detecting oscillations using coherence. In one embodiment, a method of detecting oscillations is disclosed. The method includes receiving an input signal; adding a time delay to the input signal; and estimating a coherence between the input signal and the time-delayed input signal.

In one embodiment, the coherence is greater than a predetermined threshold. The predetermined threshold may be above 0.5.

In one embodiment, the time delay is greater than or equal to one sampling interval. Alternatively, the time delay may be between 1 and 60 seconds or between 4 and 30 seconds.

The input signal may be, but is not limited to, a time series signal. The oscillations may be, but are not limited to, forced oscillations. In one embodiment, the oscillations are detected in a power transmission system.

In one embodiment, the coherence is displayed on a heat map to an operator.

In another embodiment of the present invention, a method of detecting oscillations is disclosed. The method includes receiving a time series input signal; adding a time delay to the input signal; and estimating a coherence between the input signal and the time-delayed input signal. The coherence is greater than a predetermined threshold.

In another embodiment of the present invention, a method of detecting oscillations is disclosed. The method includes receiving a time series input signal; adding a time delay to the input signal; and estimating a coherence between the input signal and the time-delayed input signal. The coherence is greater than about 0.5. The time delay is between 4 to 30 seconds, and the oscillations are detected in a power transmission system.

### BRIEF DESCRIPTION OF THE DRAWINGS

FIG. 1 illustrates a block flow diagram of a method for detecting oscillations, in accordance with one embodiment of the present invention.

FIG. 2 shows time plots of a time series signal xₜ and its sinusoidal component using a phasor measurement unit (PMU) simulation model that mimics system responses to a forced oscillation with the frequency at 6.0 Hz, the amplitude of the sinusoidal component at 0.1, and the signal-to-noise (SNR) ratio equal to −20 dB.

FIG. 3 shows, as a benchmark for detecting forced oscillations, the power spectral densities (PSDs) of xₜ for the first 34.13 seconds of data (i.e., N=1034), with L=128, Hamming windows, M=15, and overlapping=50%.

FIG. 4 shows a heat map for the PSDs of xₜ for 60 minutes of simulation data with a segment size of 34 seconds (i.e., N=1024).

FIG. 5 shows a heat map for the self-coherence spectra Cₓₓ (N=1024) as the time delay (Δt) is varied between 0 and 20 seconds.

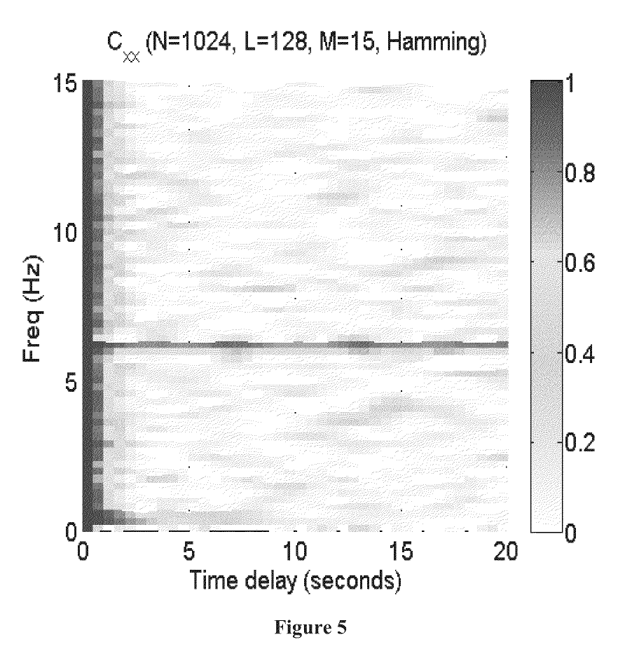

FIG. 6 shows the self-coherence spectra Cₓₓ (N=1024, Δt=6 s) for the first 34+6 seconds in the simulation data.

FIG. 7 shows a heat map for the self-coherence spectra Cₓₓ (N=1024, Δt=6 s) for 60 minutes of simulation data.

FIG. 8 is a single line diagram of a 16 machine, 68-bus system used to generate simulation data.

FIG. 9 shows a heat map of the PSDs, for purposes of comparison to the self-coherence method of the present invention, of the active power flowing from bus 1 to bus 2 for 60 minutes of simulation data from the 16-machine, 68-bus system of FIG. 8.

FIG. 10 shows a heat map for the self-coherence spectra Cₓₓ (N=1024) at the 15 minute with Δt varying between 0 and 20 seconds.

FIG. 11 shows a heat map for the self-coherence spectra C, (N=1024, Δt=6 s) for 60 minutes of simulation data from the 16-machine, 68-bus system of FIG. 8

FIG. 12 shows the self-coherence spectra C, (N=1024, Δt=6 s) of the active power from Malin to Round Mountain for 8 hours of field measurement data.

FIG. 13 shows the self-coherence spectra C, (N=1024, Δt=6 s) of the active power from Malin to Round Mountain for 60 minutes between the 3^{rd} and 4^{th} hours.

FIG. 14 shows the PSDs, for purposes of comparison to the self-coherence method of the present invention, for the active power flow from Malin to Round Mountain for 60 minutes between the 3^{rd} and 4^{th} hours.

FIG. 15 shows the self-coherence spectra C, (N=1024) at the 15 minute for different Δt.

### DETAILED DESCRIPTION OF THE PREFERRED EMBODIMENTS

The present invention is directed to methods and systems for detecting oscillations using coherence. Disclosed is a “self-coherence” method or spectrum for detecting and analyzing oscillations. In one embodiment, forced oscillations are detected and analyzed using PMU data. The self-coherence method of the present invention is a coherence spectrum between a signal and its time delayed signal.

Random ambient noise diminished as the time delay increased. In contrast, the self-coherence of a sustained oscillation remained at a peak level, even with a long time delay. Therefore, sustained oscillations are related to the peaks in self-coherence spectra with a proper time delay. A threshold can be set up on a self-coherence spectrum to detect sustained oscillations under random ambient noise. Performance evaluation based on simulations and field measurement data shows that the self-coherence method can detect forced oscillations and estimate their frequencies under low SNRs. The accuracy of the self-coherence method is compared with a PSD method and demonstrates superior performance. The computation speed of the method is fast enough for real-time implementation.

### A Review of Coherence Analysis

The coherence spectrum, also known as “magnitude squared coherence” at frequency f between two time-series signals, yₜ and xₜ, is defined in Eq. (1) below (*references*). Here, Pₓₓ and P_{yy} are the power spectral density (PSD) of the signals xₜ and yₜ, respectively. P_{xy} is the cross-spectral density.

$${C}_{xy} ( f ) {=}^{Δ} \frac{{\vert {P}_{xy} ( f ) \vert}^{2}}{{P}_{xx} ( f ) {P}_{yy} ( f )} \qquad ( 1 )$$

The value of C_{xy}(f) reflects how well yₜ and xₜ are linearly correlated at frequency f. It can be viewed as the percentage power of yₜ that can be linearly explained by xₜ at frequency f. For example, if xₜ is a sinusoidal signal at frequency fₓ Hz and yₜ is another sinusoidal signal at frequency f_{y} Hz, then the relationship in Eq. (2) holds. In addition, C_{xy} always takes real values and satisfies Eq. (3).

$$\begin{matrix}\{ \begin{matrix}{C}_{xy} ( {f}_{x} ) = {C}_{xy} ( {f}_{y} ) = 1 & if {f}_{x} = {f}_{y} \\ {C}_{xy} ( {f}_{x} ) = {C}_{xy} ( {f}_{y} ) = 0 & if {f}_{x} \neq {f}_{y}\end{matrix} & ( 2 ) \\ 0 \leq {C}_{xy} ( f ) \leq 1 \\ ∀ f ∈ R & ( 3 )\end{matrix}$$

The coherence spectrum can be estimated from time-series measurements. Assume that xₜ, yₜ are sampled at the rate of Fₛ samples/s (whose corresponding sampling interval is Tₛ=1/Fₛ s). The corresponding time-series measurements can be described by Eq. (4).

x[n]=x_{t=nT}_{ₛ},y[n]=y_{t=nT}_{ₛ} for n=0,1, . . . ,N−1 (4)

Then, the cross power spectrum P_{xy} in (1) can be estimated using Welch's method through the fast Fourier transform (FFT) algorithm (J. Pierre and R. F. Kubichek, “Spectral Analysis: Analyzing a Signal Spectrum,” Tektronix Application Note, 2002). Here, y[n] and x[n] are initially divided into data segments of length L with 50% overlapping. Secondly, a Hamming window, w[n], is applied at each segment of data, and the FFTs of windowed y[n] and x[n] are calculated using Eq. (5). Finally, the P_{xy}(fₖ) can be estimated using Eq. (6), where the superscript “*” represents a complex conjugate operation. The Pₓₓ(fₖ) and P_{yy}(fₖ) in (1) can be estimated as a special case of P_{xy}(fₖ) using Eq. (5) and Eq. (6). To estimate a coherence spectrum, MATLAB® provides the function “mscohere.”

$$\begin{matrix}{X}_{m} ( {f}_{k} ) = \frac{1}{\sqrt{U}} {\sum }_{n = ( m - 1 ) L / 2}^{( m + 1 ) L / 2 - 1} w [ n ] x [ n ] exp ( - j 2 π kn / L ) & ( 5. a ) \\ {Y}_{m} ( {f}_{k} ) = \frac{1}{\sqrt{U}} {\sum }_{n = ( m - 1 ) L / 2}^{( m + 1 ) L / 2 - 1} w [ n ] y [ n ] exp ( - j 2 π kn / L ) & ( 5. b ) \\ where \\ k = 0 , 1 , 2 , … , L - 1 \\ and \\ {f}_{k} = {kF}_{s} / L \\ m = 1 , 2 , … , M \\ and \\ M = 2 N / L - 1 \\ U = {\sum }_{n = 0}^{L - 1} {w}^{2} [ n ] & ( 5. c ) \\ {P}_{XY}^{( m )} ( {f}_{k} ) = \{ \begin{matrix}2 {T}_{s} {X}_{m} ( {f}_{k} ) {Y}_{m}^{*} ( {f}_{k} ) & for 0 < {f}_{k} \leq {F}_{s} / 2 \\ {T}_{s} {X}_{m} ( {f}_{k} ) {Y}_{m}^{*} ( {f}_{k} ) & for {f}_{k} = 0\end{matrix} & ( 6. a ) \\ {P}_{xy} ( {f}_{k} ) = \frac{1}{M} {\sum }_{m = 1}^{M} {P}_{XY}^{( m )} ( {f}_{k} ) & ( 6. b )\end{matrix}$$

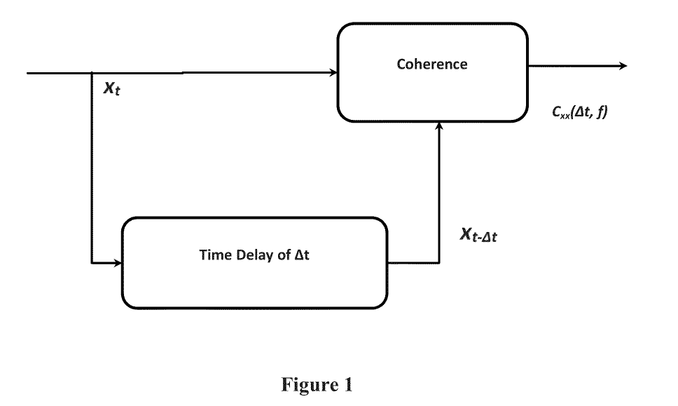

FIG. 1 illustrates a block flow diagram of a method for detecting oscillations, also referred to as a “self-coherence” method or spectrum, in accordance with one embodiment of the present invention. As illustrated in FIG. 1, a self-coherence spectrum Cₓₓ(Δt, f) is the coherence spectrum between a signal xₜ and its time-delayed signal x_{t-Δt}. Here, Δt is the time delay in seconds. In other words, the self-coherence spectrum is defined as a special case of Eq. (1) by assigning yₜ=x_{t-Δt}. As a result, the self-coherence spectrum of xₜ with time delay of Δt=d·Tₛ can be estimated from a discrete time series of x[n], using Eq. (5) and Eq. (6) by assigning y[n]=x[n−d] in Eq. (4).

In one embodiment, when only one channel of data is available a self-coherence spectrum can be used to detect sustained forced oscillations. Forced oscillations are caused by an external periodic perturbation. As in Eq. (7), a representative external periodic perturbation can be modeled as a sinusoidal signal. Here, fₑ is the frequency of the oscillation in Hz, U is the effective magnitude, and φᵤ is the phase angle.

uₜ=\sqrt{2}U sin(2πfₑt+φᵤ) (7)

Around an equilibrium operational point, the dynamic behaviors of a power system can be approximated by linear differential algebraic equations. Therefore, the responses to uₜ also are sinusoidal signals with the same frequency fₑ. In addition, there usually are additional ambient noises (nxₜ). Therefore, the system responses can be represented as xₜ in Eq. (8), and its time-delayed signal can be represented as x_{t-Δt} in Eq. (9).

yₜ=x_{tΔt}=\sqrt{2}X sin(2πfₑt+φₓ−2πfₑΔt)+nx_{t-Δt} (9)

When the sinusoidal components in Eq. (8) and Eq. (9) are larger than the noise components at fₑ, the coherence spectrum C_{xy} at fₑ Hz shall be close to 1. Meanwhile, nxₜ and nx_{t-Δt} may dominate all of the other frequencies. The following sections show the coherence between random ambient noise nxₜ and nx_{t-Δt} diminishes with an increase of Δt. Therefore, the self-coherence Cₓₓ(Δt, f) will be close to 0 at the other frequencies when Δt is large enough. As a result, the forced oscillations can be detected by setting a threshold Cₜₕᵣₑₛ for the Cₓₓ(Δt, f). If Cₓₓ(Δt, f) exceeds the preselected threshold Cₜₕᵣₑₛ, forced oscillation is detected. The frequency of the forced oscillation can be located as the center of the peaks in Cₓₓ(Δt, f). The amplitude of the forced oscillation in xₜ can be estimated using Eq. (10) (J. Pierre and R. F. Kubichek, “Spectral Analysis: Analyzing a Signal Spectrum,” Tektronix Application Note, 2002).

$$X \approx \sqrt{\frac{{P}_{xx} ( {f}_{e} )}{{T}_{s} L}} \qquad ( 10 )$$

### A Case Study Using A Simulation Model

In this section, a simulation example was used to evaluate the self-coherence method's performance in detecting and analyzing forced oscillations. This example was used to illustrate the concept and allow others to replicate and verify the results. The self-coherence method was compared with a PSD method.

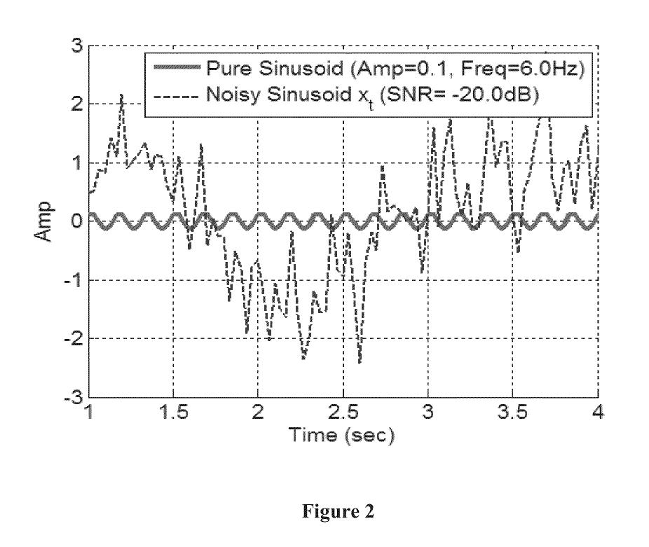

To simulate PMU measurements in this example, the simulation data were generated using Eq. (11) at a rate of 30 samples/s for 60 minutes. Here, the xₜ was used to mimic system responses to a forced oscillation with the frequency at 6.0 Hz. The eₜ is the Gaussian white noise to mimic random disturbance to a power system. The transfer function G(s) mimics a power system's low-pass feature to generate ambient noise. The three modes of G(s) are summarized in Table I. The standard deviation of ambient noise was set to 1.00. The amplitudes of the forced oscillation (i.e., X) were adjusted to make the SNR equal to −20 dB. FIG. 2 shows a sample time plot of xₜ as a blue dashed line. In addition, the sinusoidal component of xₜ is shown as the red solid line. The amplitude of the sinusoidal component (i.e., X) was 0.10, which is relatively small compared with the ambient noise component.

$$\begin{matrix} {x}_{t} = \sqrt{2} X sin ( 6.0 \cdot 2 π t + π / 4 ) + G ( s ) {e}_{t} & ( 11. a ) \\ G ( s ) = \frac{20}{s + 0.2 + 0.4 \cdot 2 π j} + \frac{20}{s + 0.2 - 0.4 \cdot 2 π j} + \frac{30}{s + 1.5 + 3.0 \cdot 2 π j} + \frac{30}{s + 1.5 - 3.0 \cdot 2 π j} + \frac{40}{s + 3.0 + 9.0 \cdot 2 π j} + \frac{40}{s + 3.0 - 9.0 \cdot 2 π j} & ( 11. b )\end{matrix}$$

TABLE I
THE SIMPLE MODEL MODES

| Mode Index | Frequency (Hz) | Damping ratio (%) | Residue |
|---|---|---|---|
| 1 | 0.4 | 7.9% | 20 |
| 2 | 3.0 | 7.9% | 30 |
| 3 | 9.0 | 5.3% | 40 |

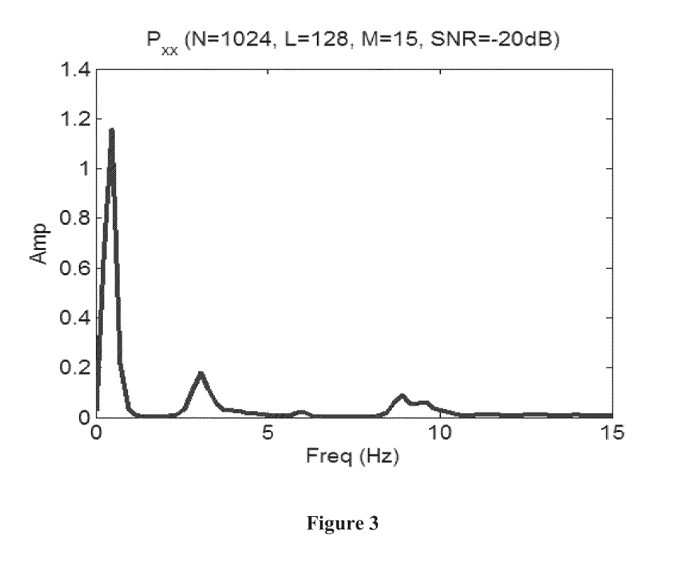

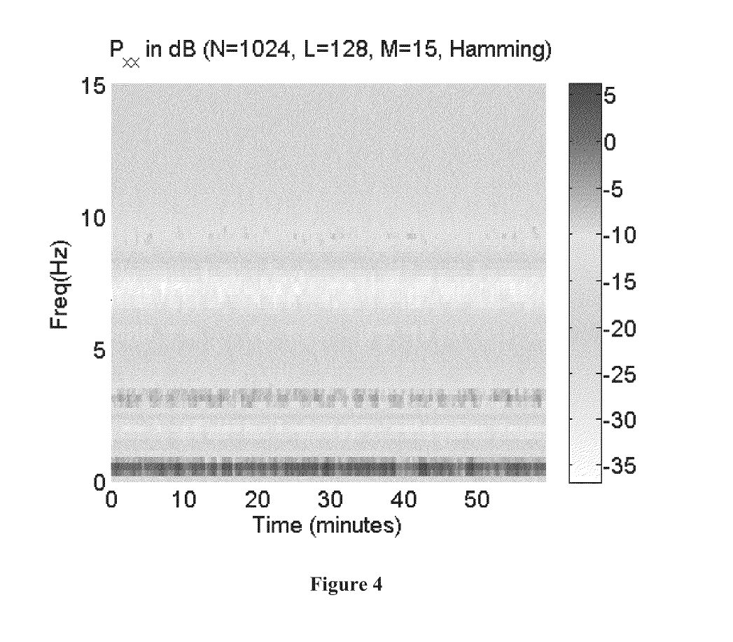

As a benchmark for detecting forced oscillation, the PSDs of xₜ for the first 34.13 seconds of data (i.e., N=1024) were calculated using Eq. (6) with L=128, Hamming windows, M=15, and overlapping=50%. FIG. 3 shows the resulting PSDs. It can be observed that the modes from the ambient noise show up as three dominant peaks at 0.4, 3.0, and 9.0 Hz. The PSDs at 6.0 Hz (i.e., the forced oscillation frequency) are much smaller than those of the ambient modes. Without prior knowledge, it is difficult to distinguish the forced oscillation from the ambient noise based only on the PSDs. To evaluate PSDs over the 60 minutes of simulation data, xₜ was divided into 209 overlapping segments. With 50% overlapping, each segment is 34.13 seconds in time duration (i.e., N=1024). The 209 PSDs were calculated and shown in FIG. 4 as a heat map. In the heat map, the PSDs' amplitudes were color coded with high amplitudes represented by red and lower amplitudes represented by white. The dB magnitudes were used to enhance the color image. Again, it is quite difficult to distinguish forced oscillations from ambient noise over the 60-minute time duration when only using the PSD plot.

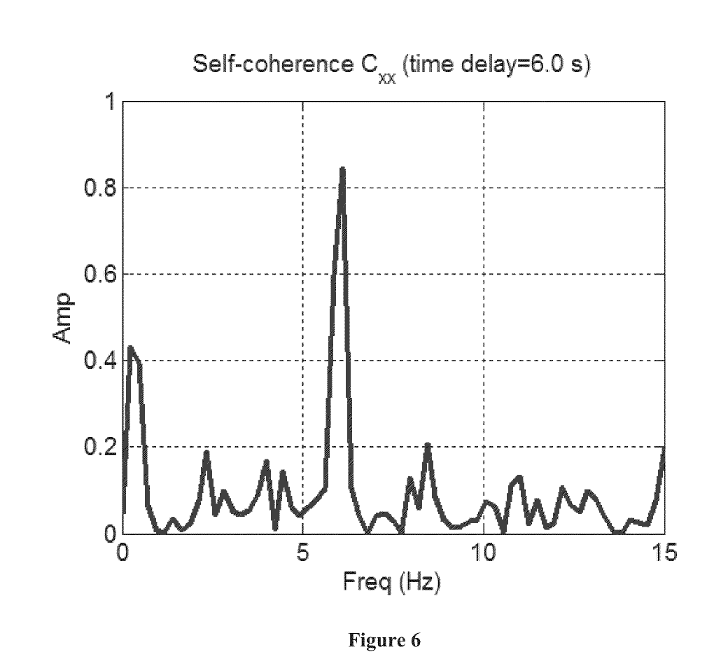

The self-coherence method was applied to the same data set. Note that a parameter in calculating self-coherence spectrum Cₓₓ is Δt. To study the influence of Δt on Cₓₓ, Δt was varied between 0 and 20 seconds, and the corresponding Cₓₓ of the first time segment was summarized in FIG. 6. It can be observed that when Δt is small (Δt≦2.0 s), the Cₓₓ at all of the frequencies is large, and it is difficult to separate the forced oscillations from ambient data. As the Δt increases, the Cₓₓ decreases at all of the frequencies, except for 6 Hz, and it becomes easy to detect for sustained oscillation at 6 Hz for Δt≧6.0 s. Note that Δt should be large enough so that coherence between the ambient noise nxₜ and nx_{t-Δt} is small. Conversely, Δt should be small enough to avoid any unnecessary time delay in detecting oscillations. Therefore, Δt=6.0 was used to calculate Cₓₓ in the following studies.

For the first 34+6 seconds of data, the self-coherence spectra of xₜ (N=1024, Δt=6 s) was estimated with L=128, Hamming windows, M=15, and overlapping=50%. FIG. 6 shows the self-coherence spectrum Cₓₓ. The most dominant peak of the Cₓₓ can be observed at 6 Hz, which corresponds to the frequency of the forced oscillation.

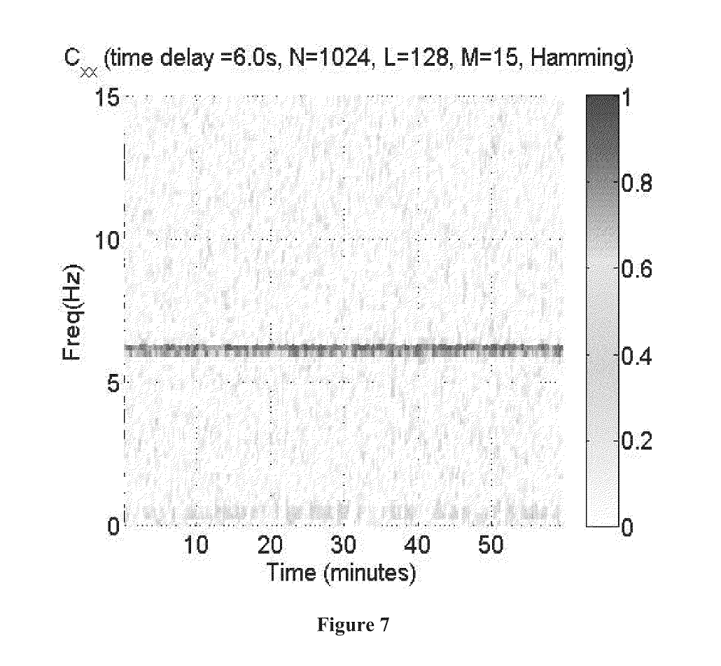

The Cₓₓ was also calculated for 60 minutes of simulation data with 50% overlapping. The resulting 209 coherence spectra are summarized in FIG. 7. There is an observable horizontal orange color line at about 6 Hz, which represents the peaks of Cₓₓ. The peak's location corresponds to the frequency of the forced oscillation.

FIG. 6 and FIG. 7 show that the forced oscillation can be readily detected by setting up a threshold on the self-coherence spectrum. Eq. (3) offers a favorable property for setting up a threshold because the values of Cₓₓ are inherently normalized between 0 and 1. Therefore, the threshold does not have to be adjusted for different channels and units. For detecting the forced oscillation, this study used, as one example, the threshold of Cₜₕᵣₑₛ=0.7. The sustained oscillation was detected for 202 out of 209 segments. Thus, the detection rate was 97%. After the oscillation was detected, the frequency of the oscillation was calculated as the weighted center of the peak in C. The amplitudes of the forced oscillation were calculated using Eq. (10) for all of the segments with detected oscillations. The root mean square errors (RMSE) of the estimated oscillation frequencies and amplitudes were calculated and listed in the first row of Table II (i.e., the row with SNR=−20 dB). The mean values of the estimates also are listed. It can be observed that the estimation accuracy and precision are reasonably good, considering the low SNR.

To evaluate the influence of SNRs on estimation precision, the amplitudes of oscillations were increased to make SNR=−10 and 0 dB. The estimation results are shown in Table II. It can be observed that the detection rates increases with the increase of SNRs. In contrast, the estimation accuracy of oscillation frequencies and amplitudes remains similar for different SNRs.

TABLE II
THE ESTIMATES OF OSCILLATION FREQUENCY
AND AMPLITUDE UNDER DIFFERENT SNRs

| | | | |
|---|---|---|---|
| SNR | Detection | Frequency (Hz) | Amplitude |

| (dB) | Rate | Mean | RMSE | Mean | RMSE |
|---|---|---|---|---|---|
| −20 | 97% | 6.03 | 0.06 | 0.11 | 0.01 |
| −10 | 100% | 6.01 | 0.05 | 0.32 | 0.01 |
| 0 | 100% | 6.03 | 0.06 | 1.00 | 0.01 |

### A Case Study Using a 16-Machine Model

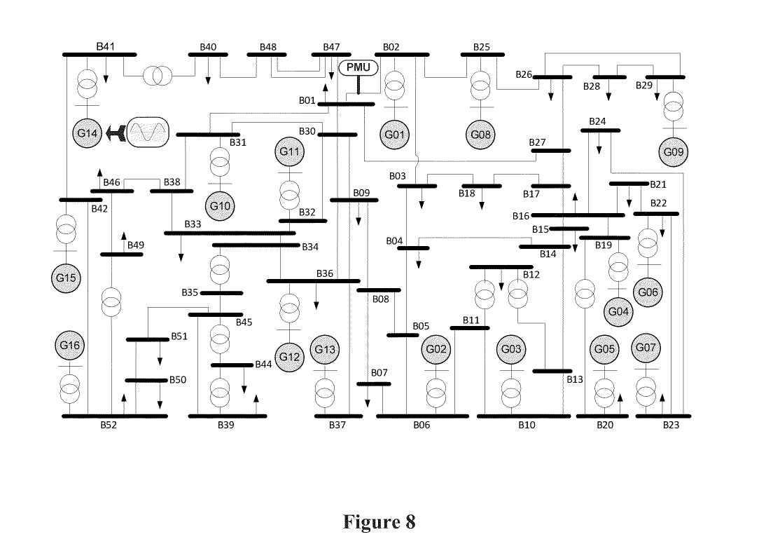

A 16-machine, 68-bus model (G. Rogers, Power System Oscillations, Kluwer, Norwell, Mass., 2000) shown in FIG. 8 was used to generate simulation data. The model comes with the Power System Toolbox (J. H. Chow and K. W. Cheung, “A toolbox for power system dynamics and control engineering education and research,” IEEE Trans. on Power Syst., vol. 7, no. 4, pp. 1559-1564, November 1992), which was used to generate simulation data. To simulate ambient noise, Gaussian white noise was added to all of the load buses via modulating the active and reactive loads by 5%. To simulate sustained forced oscillations, a 6 Hz sinusoidal signal was added from the 10th to 40th minute by modulating the exciter voltage reference of generator 14. To simulate PMU measurements, 60 minutes of active power flow from bus 1 to bus 2 was collected at the rate of 30 samples/s. The modulating signal generates the sinusoidal responses of 0.23 MW at the PMU measurement, and the corresponding SNR=−6.9 dB.

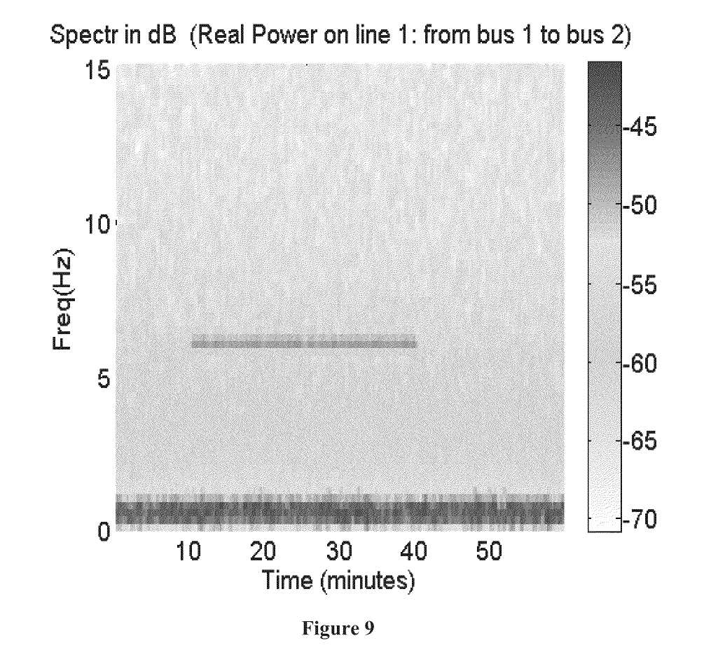

As a preprocessing procedure, a first-order, high-pass Butterworth filter—with cutoff frequency at 0.01 Hz—was applied to remove the direct current (DC) components. As a benchmark for detecting forced oscillations, the PSDs were calculated using the same setups as described in the previous section. The resulting Pₓₓ is summarized in FIG. 9. Between 10th and 40th minute, there is some observable indication of the oscillation at 6 Hz. However, PSD amplitudes at 6 Hz are lower than those below 2 Hz. Therefore, it is difficult to distinguish the forced oscillation from ambient noise over the 60-minute time duration only using the PSDs.

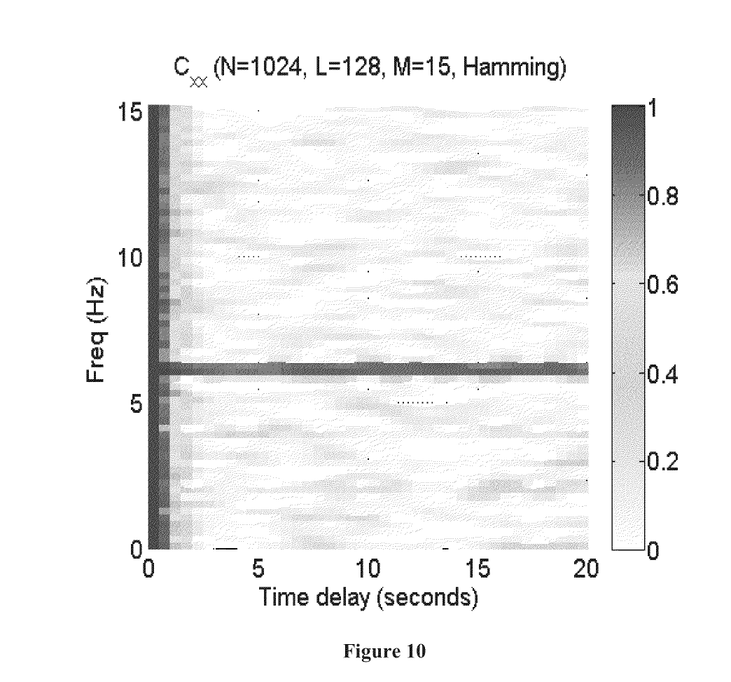

The self-coherence method was applied to the same data set. To determine the Δt, the self-coherence spectra of the data block at the 15th minute was calculated with Δt varying between 0 and 20 s. The corresponding Cₓₓ is summarized in FIG. 10. The self-coherence of ambient noise was observed diminishing for Δt≧2 seconds. In contrast, the Cₓₓ at the 6 Hz oscillation frequency was sustained. To provide a safe margin and remain consistent with the setups as in the previous section, Δt=6 s was used in the following studies even though a different Δt can be used.

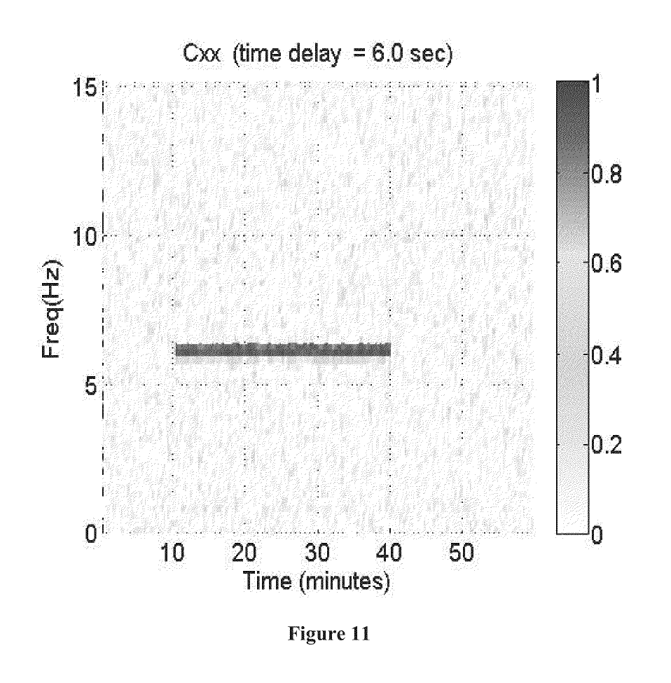

The same setups were used to calculate the Cₓₓ as shown in the previous section. FIG. 11 summarizes the results. There is an observable horizontal red color line at about 6 Hz, which represents the peaks of Cₓₓ. The peak's location corresponds to the frequency of the forced oscillation. The line starts at the 10th minute and ends at the 40th minute, which matches well with the starting and ending times of the forced oscillation. The corresponding detection rate was 100%. The mean value of the estimated oscillation frequency was 6.03 Hz, and the RMSE was 0.04 Hz. The mean value of the estimated oscillation amplitude was 0.24 MW, and the RMSE was 0.02 MW.

### A Case Study Using Field Measurement Data

The Self-coherence method was applied to field measurement data from the Western Electricity Coordinating Council (WECC) wide area measurement system. The goal was to test the self-coherence method in a real-world application.

The field measurement data included both ambient and oscillation data. The active power flow on the transmission line from Malin to Round Mountain was chosen as the testing signal because it is the measurement on major tie lines and was available. Eight hours of PMU data were obtained for the oscillation study.

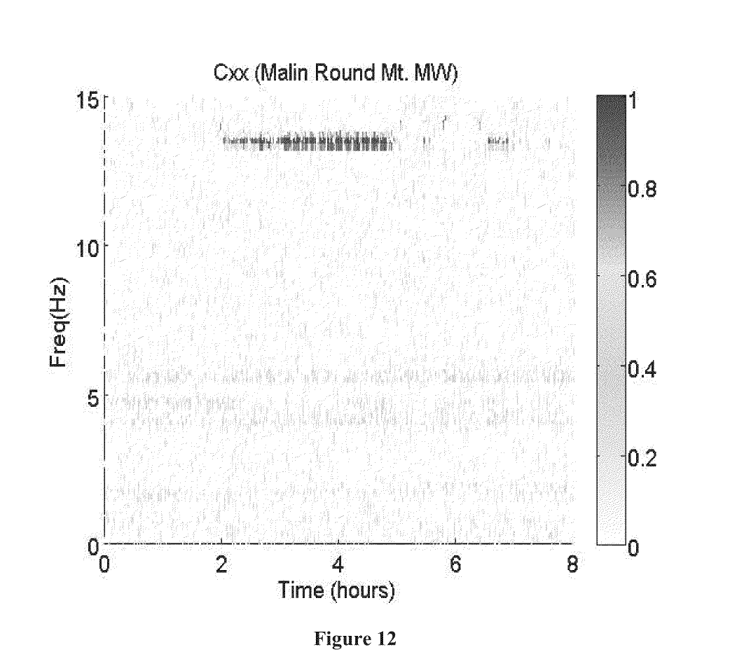

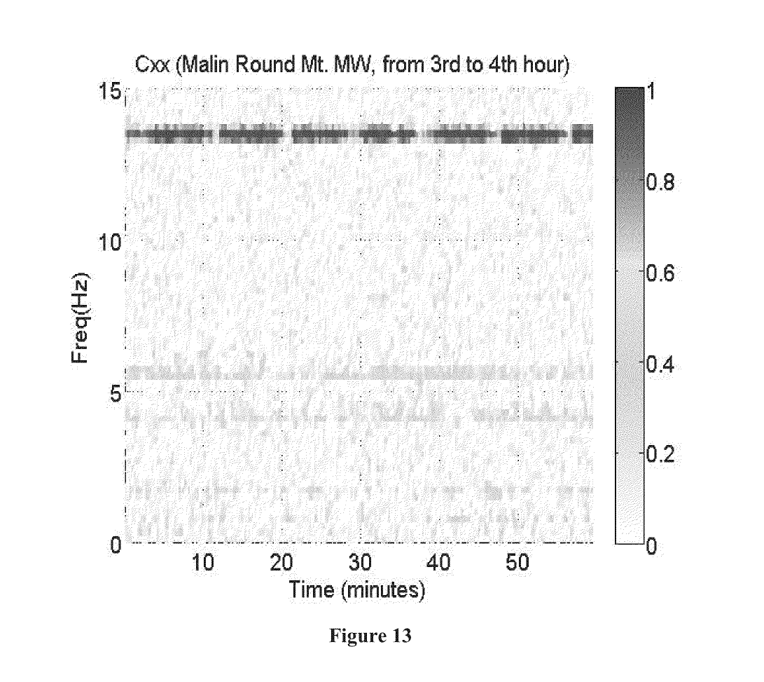

The self-coherence method was applied with same setups (e.g., Δt=6 s, N=1024, L=128, and M=15) as the previous section. The resulting self-coherence spectra are shown in FIG. 12. It can be observed that coherence spectra were low most of time, which indicates ambient data. Between the 2nd and 5th hours, the self-coherence level was high at 13 Hz. A zoom-in plot of the coherence spectra between the 3rd and 4th hours is shown in FIG. 13.

For those 60 minutes of active power flow data, the mean value of the estimated oscillation frequencies was 13.35 Hz, and the standard deviation was 0.05 Hz. The mean value of the estimated oscillation amplitudes was 0.071 MW, and the standard deviation of the estimates was 0.004 MW. In contrast, the standard deviation of the total active power flow was 2.85 MW, which indicates about −32 dB in SNR. The detected oscillations can be associated with a system oscillation event hundreds of miles away from Malin. Other measurement channels also were tried, and similar observations apply.

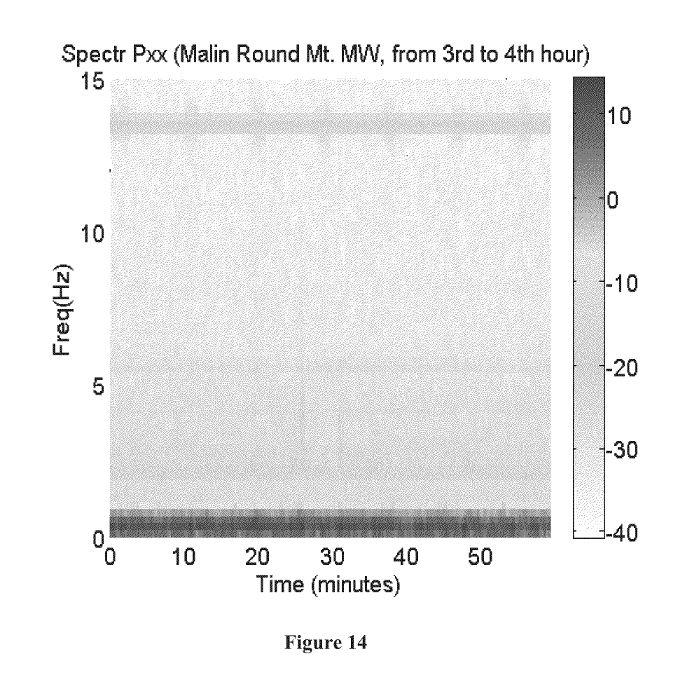

In comparison, FIG. 14 depicts the PSDs for those same 60 minutes of the active power flow data. The oscillation at 13 Hz can be spotted, but its amplitudes were much smaller than those below 2.0 Hz. Therefore, it is difficult to set up a threshold in the PSDs to distinguish the forced oscillation from ambient noise.

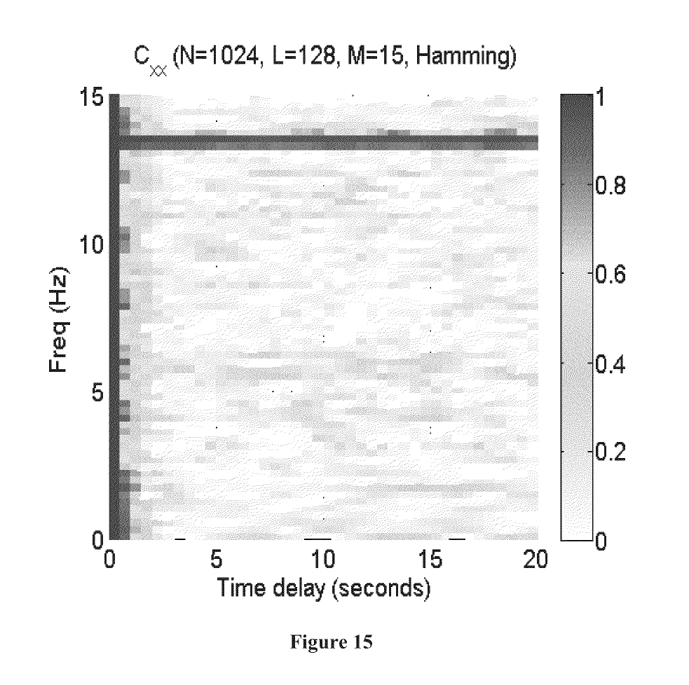

To evaluate the sensitivity of the self-coherence spectrum to the time delay, the Cₓₓ of the data segment at the 15th minute was calculated with Δt varying between 0 and 20 s. FIG. 15 summarizes the resulting C. It can be observed that the self-coherence of ambient noise diminishes for Δt>2.5 s. In contrast, the Cₓₓ at about 13 Hz was sustained. Therefore, setting Δt=6 s offered a safe margin for reliably detecting the oscillation.

The preceding data-processing procedures were implemented using MATLAB® version 2011a and completed on a computer with a 3.2-GHz processor and 6 GB of memory. It took 13.6 seconds to complete all of the coherence and PSD analyses for the 60 minutes of data. Therefore, the computation speed of the method is faster than the PMU data stream and can be applied to detect oscillations in real time. In addition, with the FFT library available to C/C++, the method can be readily implemented using C/C++.

As shown in the examples above, the self-coherence spectrum of random ambient noise diminished as the time delay increased. In contrast, the self-coherence of a sustained oscillation remained at a peak level, even with a long time delay. Therefore, sustained oscillations are related to the peaks in self-coherence spectra with a proper time delay. A threshold can be set up on a self-coherence spectrum to detect sustained oscillations under random ambient noise. Performance evaluation based on simulation and field measurement data showed that the self-coherence method can detect forced oscillations and estimate their frequencies under low SNRs. The accuracy of the self-coherence method was compared with a PSD method and demonstrated superior performance. The computation speed of the method was fast enough for real-time implementation.

The present invention has been described in terms of specific embodiments incorporating details to facilitate the understanding of the principles of construction and operation of the invention. As such, references herein to specific embodiments and details thereof are not intended to limit the scope of the claims appended hereto. It will be apparent to those skilled in the art that modifications can be made in the embodiments chosen for illustration without departing from the spirit and scope of the invention.

We claim:

1. A method of detecting oscillations comprising:
a. receiving an input signal;
b. adding a time delay to the input signal;
c. estimating a coherence between the input signal and the time-delayed input signal.

2. The method of claim 1 wherein the coherence is greater than a predetermined threshold.

3. The method of claim 2 wherein the predetermined threshold is above 0.5.

4. The method of claim 1 wherein the time delay is greater than or equal to one sampling interval.

5. The method of claim 1 wherein the time delay is between 1-60 seconds.

6. The method of claim 5 wherein the time delay is between 4-30 seconds.

7. The method of claim 1 wherein the input signal is a time series signal.

8. The method of claim 1 wherein the oscillations are forced oscillations.

9. The method of claim 1 wherein the oscillations are detected in a power transmission system.

10. The method of claim 1 wherein the coherence is displayed on a heat map to an operator.

11. A method of detecting oscillations comprising:
a. receiving a time series input signal;
b. adding a time delay to the input signal; and
c. estimating a coherence between the input signal and the time-delayed input signal, wherein the coherence is greater than a predetermined threshold.

12. The method of claim 11 wherein the predetermined threshold is above 0.5.

13. The method of claim 11 wherein the time delay is greater than or equal to one sampling interval.

14. The method of claim 11 wherein the time delay is between 1-60 seconds.

15. The method of claim 14 wherein the time delay is between 4-30 seconds.

16. The method of claim 11 wherein the oscillations are forced oscillations.

17. The method of claim 11 wherein the oscillations are detected in a power transmission system.

18. The method of claim 11 wherein the coherence is displayed on a heat map to an operator.

19. A method of detecting oscillations comprising:
a. receiving a time series input signal;
b. adding a time delay to the input signal; and
c. estimating a coherence between the input signal and the time-delayed input signal, wherein the coherence is greater than about 0.5, the time delay is between 4-30 seconds, and the oscillations are detected in a power transmission system.

20. The method of claim 19 wherein the oscillations are forced oscillations or free oscillations.

21. The method of claim 19 wherein the coherence is displayed on a heat map to an operator.
